(19) United States
(12) Patent Application Publication
(10) Pub. No.: US 2026/0282369 A1
(43) Pub. Date: Sep. 17, 2026

(54) MEMORY DEVICE

(71) Applicant: Kioxia Corporation, Tokyo (JP)

(72) Inventors: Toru NAKANISHI, Kawagoe Mie (JP); Daisuke HAGISHIMA, Setagaya Tokyo (JP)

(21) Appl. No.: 19/319,664

(22) Filed: Sep. 4, 2025

(30) Foreign Application Priority Data
Mar. 14, 2025 (JP) 2025-041537

(51) Int. Cl. H10B 43/35; H10B 41/10; H10B 41/20; H10B 41/35; H10B 43/10; H10B 43/20

(52) U.S. Cl. CPC H10B 43/35; H10B 41/10; H10B 41/20; H10B 41/35; H10B 43/10; H10B 43/20

(57) ABSTRACT

A memory device includes a plurality of semiconductor layers separated from each other in a first direction, a plurality of conductive members penetrating the semiconductor layers in the first direction, a plurality of first insulating films surrounding side surfaces of the conductive members, a plurality of charge storage films between the first insulating films and one of the semiconductor layers, a plurality of second insulating films between the charge storage films and the one of the semiconductor layers, and a plurality of semiconductor films between the second insulating films and the one of the semiconductor layers, and in contact with the one of the semiconductor layers. A thickness of each of the semiconductor layers in the first direction is less than a thickness of the one of the semiconductor films in the first direction.

### CROSS-REFERENCE TO RELATED APPLICATION

This application is based upon and claims the benefit of priority from Japanese Patent Application No. 2025-041537, filed Mar. 14, 2025, the entire contents of which are incorporated herein by reference.

### Field

Embodiments described herein relate generally to a memory device.

### Background

NAND flash memories capable of storing data in a non-volatile manner are known.

### BRIEF DESCRIPTION OF THE DRAWINGS

FIG. 1 is a block diagram illustrating an overall configuration of a memory device according to an embodiment.

FIG. 2 is a circuit diagram illustrating an example of a circuit configuration of a memory cell array in the memory device.

FIG. 3 is a circuit diagram illustrating an example of a circuit configuration of an odd string unit of the memory cell array in the memory device.

FIG. 4 is a circuit diagram illustrating an example of a circuit configuration of an even string unit of the memory cell array in the memory device.

FIG. 5 is a perspective view illustrating an outline of a structure of the memory cell array in the memory device.

FIG. 6 is a plan view illustrating an example of a planar layout of word lines and upper pillars in the memory cell array in the memory device.

FIG. 7 is a plan view illustrating an example of a planar layout of select gate lines and the upper pillars in the memory cell array in the memory device.

FIG. 8 is a plan view illustrating an example of a planar layout of a semiconductor layer and lower pillars in the memory cell array in the memory device.

FIG. 9 is a cross-sectional view taken along a line IX-IX in FIG. 8 and illustrating an example of a cross-sectional structure of the memory cell array in the memory device.

FIG. 10 is a cross-sectional view illustrating an example of a detailed cross-sectional structure of a string unit in the memory cell array in the memory device.

FIG. 11 is a cross-sectional view illustrating an example of a detailed cross-sectional structure of a first layer in the memory cell array in the memory device.

FIG. 12 is a cross-sectional view illustrating an example of a detailed cross-sectional structure of a second layer in the memory cell array in the memory device.

FIG. 13 is a cross-sectional view illustrating an example of a cross-sectional structure in a manufacturing process of the memory device.

FIG. 14 is a cross-sectional view illustrating an example of a cross-sectional structure in the manufacturing process of the memory device.

FIG. 15 is a cross-sectional view illustrating an example of a cross-sectional structure in the manufacturing process of the memory device.

FIG. 16 is a cross-sectional view illustrating an example of a cross-sectional structure in the manufacturing process of the memory device.

FIG. 17 is a cross-sectional view illustrating an example of a cross-sectional structure in the manufacturing process of the memory device.

FIG. 18 is a cross-sectional view illustrating an example of a cross-sectional structure in the manufacturing process of the memory device.

FIG. 19 is a cross-sectional view illustrating an example of a cross-sectional structure in the manufacturing process of the memory device.

FIG. 20 is a schematic diagram illustrating an example of a read operation of the memory device.

FIG. 21 is a schematic diagram illustrating an example of the read operation of the memory device.

### DETAILED DESCRIPTION

Embodiments provide improvement in performance of a memory device.

In general, according to one embodiment, a memory device comprises a plurality of semiconductor layers separated from each other in a first direction; a plurality of conductive members penetrating the semiconductor layers in the first direction; a plurality of first insulating films surrounding side surfaces of the conductive members; a plurality of charge storage films between the first insulating films and one of the semiconductor layers; a plurality of second insulating films between the charge storage films and said one of the semiconductor layers; and a plurality of semiconductor films between the second insulating films and said one of the semiconductor layers, and in contact with said one of the semiconductor layers. A thickness of each of the semiconductor layers in the first direction is less than a thickness of said one of the semiconductor films in the first direction.

Hereinafter, embodiments will be described with reference to the drawings. The embodiments show examples of an apparatus and a method for implementing the technical scope of the disclosure. The drawings are schematic or conceptual. Dimensions and ratios in each drawing are not necessarily the same in practice. Illustration of structures may be omitted as appropriate. Hatching applied to a plan view does not necessarily relate to materials or characteristics of elements. In the present specification, elements having substantially the same functions and structures are represented by the same reference signs. Numbers and letters applied to the reference signs are used to distinguish between similar elements referred to by the same reference signs. In the present specification, one of a source or a drain of a transistor is referred to as "one end (of current path)", and the other of the source or the drain is referred to as "the other end (of current path)". The configurations assigned to one end and the other end (source or drain) may differ for each transistor.

### 1 Configuration

First, a configuration of a memory device 1 according to an embodiment will be described.

### 1-1 Overall Configuration of Memory Device 1

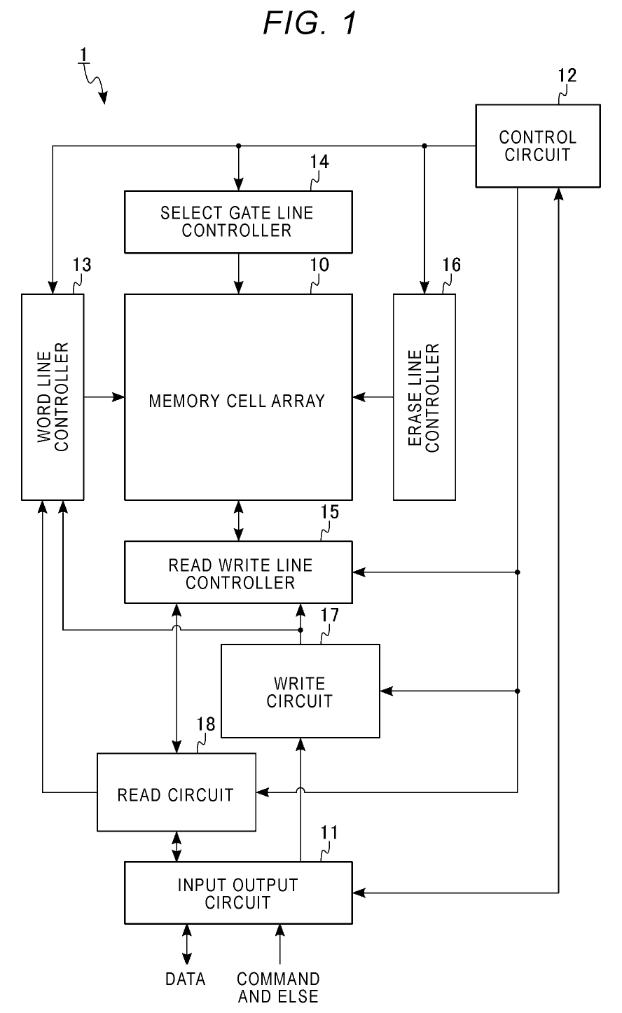

FIG. 1 is a block diagram illustrating an example of an overall configuration of the memory device 1. As illustrated in FIG. 1, the memory device 1 includes, for example, a memory cell array 10, an input output circuit 11, a control circuit 12, a word line controller 13, a select gate line controller 14, a read write line controller 15, an erase line controller 16, a write circuit 17, and a read circuit 18.

The memory cell array 10 is a storage region in which data is stored in a non-volatile manner. Although not illustrated in the drawing, the memory cell array 10 includes a plurality of memory cell transistors MC arranged three-dimensionally, a plurality of word lines WL, a plurality of select gate lines SG, a plurality of read write lines RWL_L and RWL_R, and a plurality of erase lines EL1 and EL2. Details of each of the memory cell transistors MC, the word lines WL, the select gate lines SG, the read write lines RWL_L and RWL_R, and the erase lines EL1 and EL2 will be described later.

The input output circuit 11 is connected to an external memory controller and manages communication between the memory device 1 and the memory controller. The input output circuit 11 transfers a command and the like received from the memory controller to the control circuit 12. When receiving data to be written into the memory cell array 10 (hereinafter referred to as the write data) from the memory controller, the input output circuit 11 transfers the write data to the write circuit 17. When receiving data read from the memory cell array 10 (hereinafter referred to as the read data) from the read circuit 18, the input output circuit 11 transfers the read data to the memory controller.

The control circuit 12 controls each component of the memory device 1. Specifically, the control circuit 12 is capable of controlling, as each component of the memory device 1, each of the input output circuit 11, the word line controller 13, the select gate line controller 14, the read write line controller 15, the erase line controller 16, the write circuit 17, and the read circuit 18. The control circuit 12 is capable of controlling each component of the memory device 1 and executing a read operation, a write operation, an erase operation, and the like based on a command received from the input output circuit 11. The control circuit 12 is capable of generating voltages used in various operations and applying the voltages to each component of the memory device 1.

The word line controller 13 controls voltages of the plurality of word lines WL provided in the memory cell array 10 based on control of the control circuit 12. The word line controller 13 is capable of independently controlling each of the voltages of the word lines WL associated with the memory cell transistors MC to be read or written and the word lines WL associated with the memory cell transistors MC not to be read or written.

The select gate line controller 14 controls voltages of the plurality of select gate lines SG provided in the memory cell array 10 based on control of the control circuit 12. The select gate line controller 14 is capable of independently controlling each of the voltages of the select gate lines SG associated with the memory cell transistors MC to be read or written and the select gate lines SG associated with the memory cell transistors MC not to be read or written.

The read write line controller 15 controls voltages of the plurality of read write lines RWL_L and RWL_R provided in the memory cell array 10 based on control of the control circuit 12. The read write line controller 15 is capable of independently controlling each of the voltages of the read write lines RWL_L and RWL_R.

The erase line controller 16 controls voltages of the plurality of erase lines EL1 and EL2 provided in the memory cell array 10 based on control of the control circuit 12. The erase line controller 16 is capable of independently controlling each of the voltages of the erase lines EL1 and EL2.

The write circuit 17 applies a voltage to be used for writing data to the word line controller 13 and the read write line controller 15 based on control of the control circuit 12 and write data received from the input output circuit 11.

The read circuit 18 includes a plurality of sense amplifiers. The read circuit 18 applies a voltage to be used for reading data to the word line controller 13 and the read write line controller 15 based on control of the control circuit 12. Then, each sense amplifier determines data stored in the memory cell transistor MC based on a voltage or a current of at least one of the read write lines RWL_L and RWL_R to be read. Then, the read circuit 18 transfers read data corresponding to a determination result to the input output circuit 11.

### 1-2 Circuit Configuration of Memory Cell Array 10

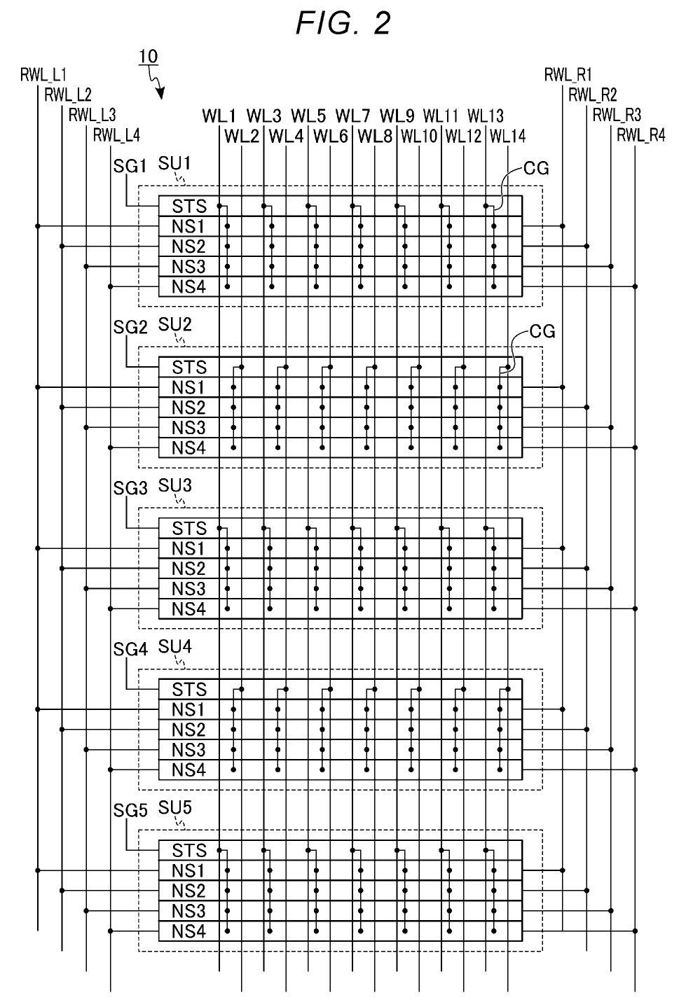

FIG. 2 is a circuit diagram illustrating an example of a circuit configuration of the memory cell array 10 in the memory device 1. As illustrated in FIG. 2, the memory cell array 10 includes, for example, a plurality of string units SU, a plurality of word lines WL, a plurality of select gate lines SG, a plurality of read write lines RWL_L, and a plurality of read write lines RWL_R. Hereinafter, an example in which the memory cell array 10 includes five string units SU1 to SU5, fourteen word lines WL1 to WL14, five select gate lines SG1 to SG5, four read write lines RWL_L1 to RWL_L4, and four read write lines RWL_R1 to RWL_R4 will be described. The number of string units SU, the number of word lines WL, the number of select gate lines SG, and the number of read write lines RWL_L and RWL_R may be each set to a different number.

Hereinafter, each odd-numbered string unit SU is referred to as an "odd string unit SUo". Each even-numbered string unit SU is referred to as an "even string unit SUe". Each odd-numbered word line WL is referred to as an "odd word line WLo". Each even-numbered word line WL is referred to as an "even word line WLe". Each odd-numbered select gate line SG is referred to as an "odd select gate line SGo". Each even numbered select gate line SG is referred to as an "even select gate line SGe".

Each string unit SU includes, for example, four NAND strings NS and a select transistor set STS. The NAND string NS is a set including memory cell transistors. The number of NAND strings NS provided in the string unit SU corresponds to the number of sets including read write lines RWL_L and RWL_R. Each NAND string NS is connected in series between one set including read write lines RWL_L and RWL_R. Specifically, the NAND string NS1 of each string unit SU is connected between the read write lines RWL_L1 and RWL_R1. The NAND string NS2 of each string unit SU is connected between the read write lines RWL_L2 and RWL_R2. The NAND string NS3 of each string unit SU is connected between the read write lines RWL_L3 and RWL_R3. The NAND string NS4 of each string unit SU is electrically connected between the read write lines RWL_L4 and RWL_R4. One set including read write lines RWL_L and RWL_R may be shared between a plurality of string units SU.

The select transistor sets STS of the string units SU1 to SU5 are each connected to the select gate lines SG1 to SG5. That is, the select gate line SG is provided independently for each string unit SU. The select transistor set STS of the odd string unit SUo is connected to each odd word line WLo. That is, each odd word line WLo is shared by the plurality of odd string units SUo. The select transistor set STS of the even string unit SUe is connected to each even word line WLe. That is, each even word line WLe is shared by the plurality of even string units SUe. Each odd word line WLo connected to the odd string unit SUo is connected to a control gate line CG via the select transistor set STS. Each even word line WLe connected to the even string unit SUe is connected to the control gate line CG via the select transistor set STS. Each control gate line CG is connected to the NAND strings NS1 to NS4.

The read write lines RWL_L and RWL_R are used to read and write data from and to, for example, the NAND string NS. The word line WL is used, for example, to select the memory cell transistor MC to be read or written, to apply a read voltage or a program voltage, and the like. The select gate line SG is used, for example, to select the string unit SU to be read or written. The erase lines EL1 and EL2 are used, for example, to erase data from the plurality of NAND strings NS.

### 1 Circuit Configuration of Odd String Unit Suo

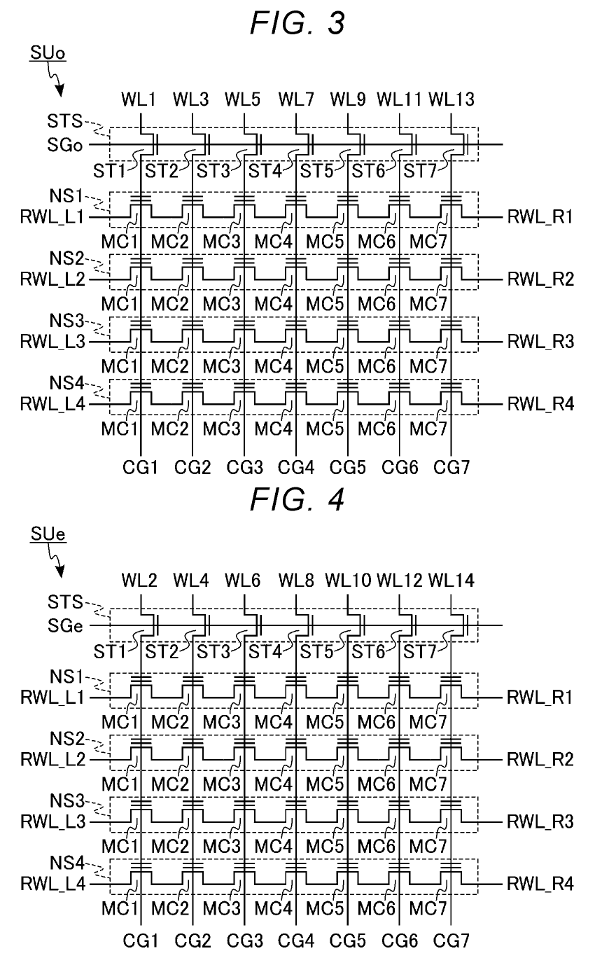

FIG. 3 is a circuit diagram illustrating an example of a circuit configuration of the odd string unit SUo of the memory cell array 10 in the memory device 1. As illustrated in FIG. 3, the odd string unit SUo includes, for example, seven control gate lines CG1 to CG7. In the odd string unit SUo, for example, each NAND string NS includes seven memory cell transistors MC1 to MC7, and the select transistor set STS includes seven select transistors ST1 to ST7. The control gate lines CG, the select transistors ST, and the memory cell transistors MC provided in the odd string unit SUo may be each set to a different number.

Each memory cell transistor MC includes a control gate and a charge storage film. Each memory cell transistor MC is capable of storing data in a non-volatile manner according to an amount of electrons injected into the charge storage film. In each NAND string NS, the memory cell transistors MC1 to MC7 are connected in series using one end and the other end. One end of the memory cell transistors MC1 to MC7 connected in series corresponds to one end of the memory cell transistor MC1. The other end of the memory cell transistors MC1 to MC7 connected in series corresponds to the other end of the memory cell transistor MC7. One end of the memory cell transistor MC1 of each of the NAND strings NS1 to NS4 is connected to each of the read write lines RWL_L1 to RWL_L4. The other end of the memory cell transistor MC7 of each of the NAND strings NS1 to NS4 is connected to each of the read write lines RWL_R1 to RWL_R4.

Each select transistor ST is used, for example, to select the string unit SU. A gate of each select transistor ST of the odd string unit SUo is connected to the associated odd select gate line SGo. One end of each of the select transistors ST1, ST2, ST3, ST4, ST5, ST6, and ST7 of the odd string unit SUo is connected to each of the word lines WL1, WL3, WL5, WL7, WL9, WL11, and WL13. That is, each select transistor ST of the odd string unit SUo is connected to a different odd word line WLo. The other end of each of the select transistors ST1 to ST7 is connected to each of the control gate lines CG1 to CG7. A control gate of each of the memory cell transistors MC1 to MC7 of each NAND string NS is connected to each of the control gate lines CG1 to CG7.

### 2 Circuit Configuration of Even String Unit Sue

FIG. 4 is a circuit diagram illustrating an example of a circuit configuration of the even string unit SUe of the memory cell array 10 in the memory device 1. As illustrated in FIG. 4, the even string unit SUe includes, for example, seven control gate lines CG1 to CG7. In the even string unit SUe, for example, each NAND string NS includes seven memory cell transistors MC1 to MC7, and the select transistor set STS includes seven select transistors ST1 to ST7. The control gate lines CG, the select transistors ST, and the memory cell transistors MC provided in the even string unit SUe may be each set to a different number.

A gate of each select transistor ST in the even string unit SUe is connected to the associated even select gate line SGe. One end of each of the select transistors ST1, ST2, ST3, ST4, ST5, ST6, and ST7 in the even string unit SUe is connected to each of the word lines WL2, WL4, WL6, WL8, WL10, WL12, and WL14. That is, each select transistor ST of the even string unit SUe is connected to a different even word line WLe. The rest of the circuit configuration of the even string unit SUe is the same as the circuit configuration of the odd string unit SUo.

### 1-3 Structure of Memory Cell Array 10

Next, the structure of the memory cell array 10 in the memory device 1 will be described. Hereinafter, in the drawings used as a reference, a three-dimensional orthogonal coordinate system is used. An X direction corresponds to a direction parallel to a surface of a semiconductor substrate of the memory cell array 10 used as a reference. A Y direction corresponds to a direction parallel to the surface of the semiconductor substrate used as a reference and intersecting the X direction. The Z direction corresponds to a direction perpendicular to the surface of the semiconductor substrate used as a reference. "Up and down" are defined based on a direction along the Z direction. A positive direction (i.e., an upward direction) corresponds to a direction moving away from the semiconductor substrate used as a reference. An XY plane (i.e., a cross section) corresponds to a plane (i.e., a cross section) parallel to each of the X direction and the Y direction. A YZ cross section corresponds to a cross section parallel to each of the Y direction and the Z direction. An XZ cross section corresponds to a cross section parallel to each of the X direction and the Z direction. "Planar direction" corresponds to a direction parallel to the surface of the semiconductor substrate and includes the X direction and the Y direction. "Planar view" or "Top view" corresponds to, for example, viewing the surface of the semiconductor substrate from a perpendicular direction of the semiconductor substrate.

### 1 Outline of Structure of Memory Cell Array 10

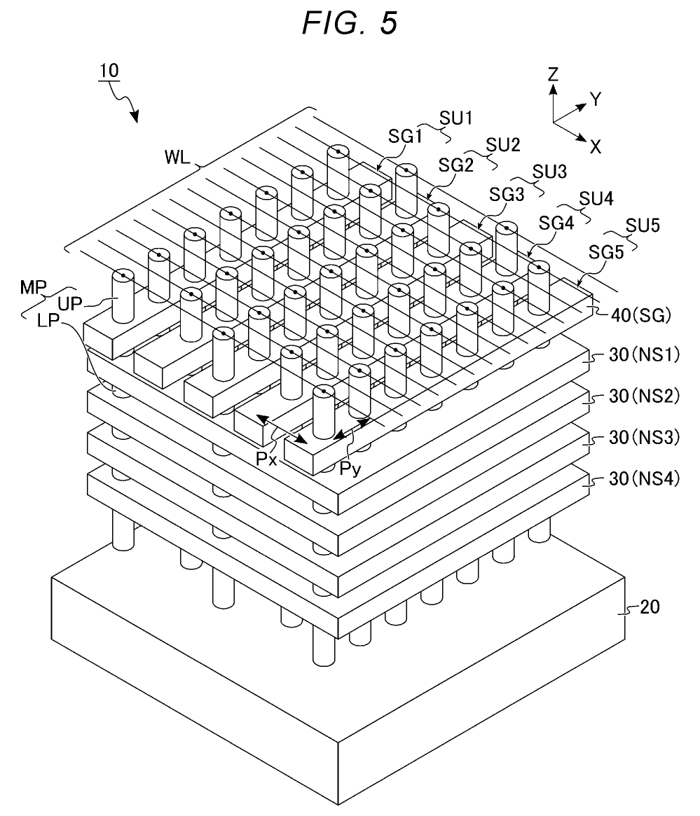

FIG. 5 is a perspective view illustrating an outline of a structure of the memory cell array 10 in the memory device 1. As illustrated in FIG. 5, the memory device 1 includes a semiconductor substrate 20. The memory cell array 10 includes, for example, a plurality of semiconductor layers 30, a plurality of conductor layers 40, and a plurality of memory pillars MP.

The semiconductor substrate 20 is a substrate used to form the memory device 1. The semiconductor substrate 20 is , for example, a single crystal semiconductor formed from one crystal such as silicon (Si) or germanium (Ge), or a compound semiconductor formed from a plurality of crystals (mixed crystals).

The plurality of semiconductor layers 30 are provided above the semiconductor substrate 20. Each semiconductor layer 30 includes a portion extending along the XY plane. The plurality of semiconductor layers 30 are arranged to be separated from each other and aligned in the Z direction. Each semiconductor layer 30 is associated with one NAND string NS of each of the plurality of string units SU1 to SU5 provided in the memory cell array 10. For example, four semiconductor layers 30 are associated with each of the NAND strings NS1 to NS4 in order from the semiconductor layer 30 furthest from the semiconductor substrate 20.

The plurality of conductor layers 40 are provided above the plurality of semiconductor layers 30. Each conductor layer 40 includes a portion extending along the Y direction. The plurality of conductor layers 40 are arranged to be separated from each other and aligned in the X direction. Each conductor layer 40 corresponds to the select gate line SG independently provided. For example, five conductor layers 40 aligned in the X direction are associated with each of the select gate lines SG1 to SG5. That is, five conductor layers 40 aligned in the X direction are associated with each of the string units SU1 to SU5.

Each memory pillar MP is a substantially cylindrical member extending in the Z direction. Each memory pillar MP penetrates (or passes through) any of the plurality of conductor layers 40 and each of the plurality of semiconductor layers 30. For example, a pitch Px (or a distance) of the plurality of memory pillars MP aligned in the X direction among the plurality of memory pillars MP is substantially constant. A pitch Py (or a distance) of the plurality of memory pillars MP aligned in the Y direction among the plurality of memory pillars MP is substantially constant. A set including the plurality of memory pillars MP aligned in the Y direction among the plurality of memory pillars MP penetrates the same conductor layer 40 (select gate line). A position of a set including the plurality of memory pillars MP penetrating the even select gate lines SGe are shifted in the Y direction by a length shorter than the pitch Py of the plurality of memory pillars MP aligned in the Y direction (for example, Py/2) relative to a position of a set including the plurality of memory pillars MP penetrating the odd select gate lines SGo. As such, the plurality of memory pillars MP are disposed in a staggered arrangement in a plan view.

Each memory pillar MP has a structure in which an upper pillar UP and a lower pillar LP are connected in the Z direction. The upper pillar UP is a substantially cylindrical member extending in the Z direction and includes a portion penetrating the associated conductor layer 40. The lower pillar LP is a substantially cylindrical member extending in the Z direction and includes a portion penetrating the plurality of semiconductor layers 30. For example, a bottom portion of the lower pillar LP is separated from the semiconductor substrate 20. An upper portion of the upper pillar UP is connected to the word line WL. Specifically, each word line WL includes a portion extending in the X direction. The plurality of word lines are aligned in the Y direction. Each odd word line WLo is aligned in the X direction and is connected to the upper portion of the plurality of upper pillars UP and each penetrating the associated odd select gate line SGo. Each even word line WLe is aligned in the X direction and is connected to the upper portion of the plurality of upper pillars UP and each penetrating the associated even select gate line SGe.

### 2 Planar Layout of Word Lines WL and Upper Pillars UP

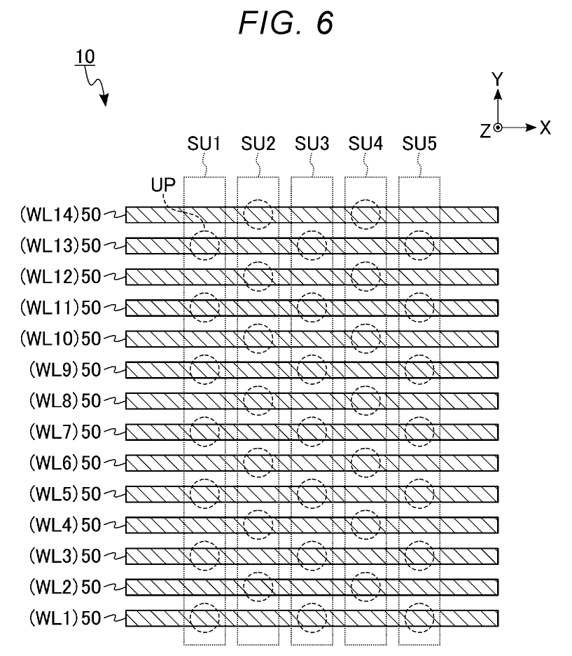

FIG. 6 is a plan view illustrating an example of a planar layout of the word lines WL and the upper pillars UP in the memory cell array 10 in the memory device 1. As illustrated in FIG. 6, the memory cell array 10 includes, for example, a plurality of conductor layers 50.

Each conductor layer 50 includes a portion extending along the X direction. The plurality of conductor layers 50 are arranged to be separated from each other and aligned in the Y direction. Each conductor layer 50 corresponds to the word line WL independently provided. For example, fourteen conductor layers 40 aligned in the Y direction are associated with each of the word lines WL1 to WL14. Each odd word line WLo (WL1, WL3, WL5, WL7, WL9, WL11, and WL13) includes a portion overlapping with the upper pillar UP of each odd string unit SUo (SU1, SU3, and SU5) in a plan view. Each even word line WLe (WL2, WL4, WL6, WL8, WL10, WL12, and WL14) includes a portion overlapping with the upper pillar UP of each even string unit SUe (SU2 and SU4) in a plan view.

### 3 Planar Layout of Select Gate Line SG and Upper Pillar UP

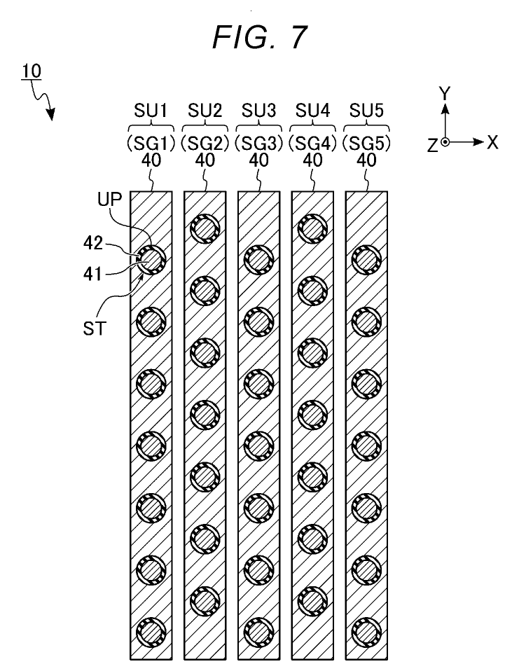

FIG. 7 is a plan view illustrating an example of a planar layout of the select gate lines SG and the upper pillars UP in the memory cell array 10 in the memory device 1. As illustrated in FIG. 7, each upper pillar UP includes, for example, a semiconductor member 41 and an insulating film 42.

The semiconductor member 41 is a semiconductor having a substantially cylindrical shape extending in the Z direction. In a plan view, the insulating film 42 covers a side surface of the semiconductor member 41. In a plan view, the associated conductor layer 40 covers a side surface of the insulating film 42. The semiconductor member 41 of each upper pillar UP is separated and insulated from the associated conductor layer 40 via the insulating film 42. A portion where the semiconductor member 41 and the conductor layer 40 intersect functions as the select transistor ST. That is, the semiconductor member 41 functions as a channel of the select transistor ST, and the insulating film 42 functions as a gate insulating film of the select transistor ST. For example, when a portion of the semiconductor member 41 intersecting the conductor layer 40 is made of a P-type semiconductor containing phosphorus (P) or arsenic (As), the select transistor ST functions as an N-channel MOSFET. The select transistor ST is not limited thereto as long as the select transistor ST is a switching element.

### 4 Planar Layout of Semiconductor Layer 30 and Lower Pillar LP

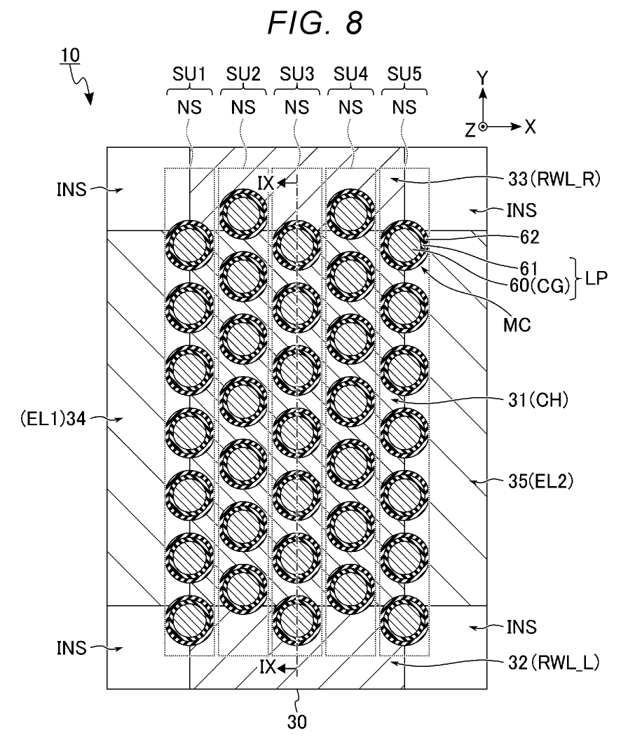

FIG. 8 is a plan view illustrating an example of a planar layout of the semiconductor layer 30 and the lower pillars LP in the memory cell array 10 in the memory device 1. As illustrated in FIG. 8, each lower pillar LP includes, for example, a conductive member 60 and a stacked film 61. A stacked film 62 is provided around each lower pillar LP.

The conductive member 60 is a conductor having a substantially cylindrical shape extending in the Z direction. The conductive member 60 is, for example, conductive polysilicon containing impurities, metal, metal silicide, or the like. In a plan view, the stacked film 61 covers a side surface of the conductive member 60. In a plan view, the stacked film 62 covers a side surface of the stacked film 61. In a plan view, the semiconductor layer 30 covers a side surface of the stacked film 62. The conductive member 60 of each lower pillar LP is separated from the semiconductor layer 30 via the stacked films 61 and 62. A portion where the conductive member 60 and the semiconductor layer 30 intersect functions as the memory cell transistor MC. That is, the conductive member 60 functions as a gate electrode of the memory cell transistor MC. The semiconductor layer 30 includes a portion functioning as a channel CH of the memory cell transistor MC.

Specifically, each semiconductor layer 30 includes, for example, a channel region 31, diffusion regions 32, 33, 34, and 35, and a plurality of insulating regions INS. The channel region 31 is, for example, an intrinsic semiconductor and functions as the channel CH of each memory cell transistor MC. The channel region 31 is in contact with the stacked film 62 provided around each of the plurality of lower pillars LP penetrating the semiconductor layer 30. At least a portion of the stacked film 62 provided around the plurality of lower pillars LP disposed in a peripheral portion among the lower pillars LP disposed in a staggered arrangement is in contact with the channel region 31. In a plan view, the channel region 31 surrounds the stacked film 62 provided around each of the lower pillars LP disposed inward of the peripheral portion among the lower pillars LP disposed in a staggered arrangement. The channel region 31 includes a portion facing the conductive member 60 of each lower pillar LP in the planar direction.

Each of the diffusion regions 32 and 33 is an N-type semiconductor region containing, for example, phosphorus (P) or arsenic (As) as impurities. The diffusion regions 32 and 33 are disposed, for example, at each of one end of the semiconductor layer 30 in the Y direction and the other end of the semiconductor layer 30 in the Y direction. The channel region 31 is interposed between the diffusion regions 32 and 33 in the Y direction. Each of the read write lines RWL_L and RWL_R is connected to each of the diffusion regions 32 and 33.

Each of the diffusion regions 34 and 35 is a P-type semiconductor region containing, for example, boron (B) as impurities. The diffusion regions 34 and 35 are disposed, for example, at each of one end of the semiconductor layer 30 in the X direction and the other end of the semiconductor layer 30 in the X direction. The channel region 31 is interposed between the diffusion regions 34 and 35 in the X direction. Each of the erase lines EL1 and EL2 is connected to each of the diffusion regions 34 and 35.

The insulating region INS insulates between the diffusion regions 32 and 34, between the diffusion regions 33 and 34, between the diffusion regions 32 and 35, and between the diffusion regions 33 and 35. As such, the insulating region INS is used as an element isolation area. According to the circuit configuration of the memory cell array 10, each of the diffusion regions 32 and 33 may be a P-type semiconductor region, and each of the diffusion regions 34 and 35 may be an N-type semiconductor region.

An interval of the semiconductor layer 30 (channel region 31) between two lower pillars LP adjacent in the Y direction is determined such that an electrical conduction path can be generated between the diffusion regions 32 and 33 via the selected NAND string NS during the read or write operation. An interval of the semiconductor layer 30 between two lower pillars LP adjacent in the X direction is determined such that an electrical conduction path can be generated between the diffusion regions 34 and 35 via each NAND string NS during the erase operation. Whether an electrical conduction path is generated during various operations depends on characteristics of the channel region 31, a voltage applied to each control gate line CG, a stacked structure of the memory cell array 10, and the like. Meanwhile, an interval of the semiconductor layer 30 between two adjacent lower pillars LP is determined to be, for example, 50 nm or less (other than 0) considering miniaturization and ease of generating an electrical conduction path. An interval of the semiconductor layer 30 between the two adjacent lower pillars LP is preferably 20 nm or less, and more preferably 10 nm or less.

### 5 Cross-Sectional Structure of Memory Cell Array 10

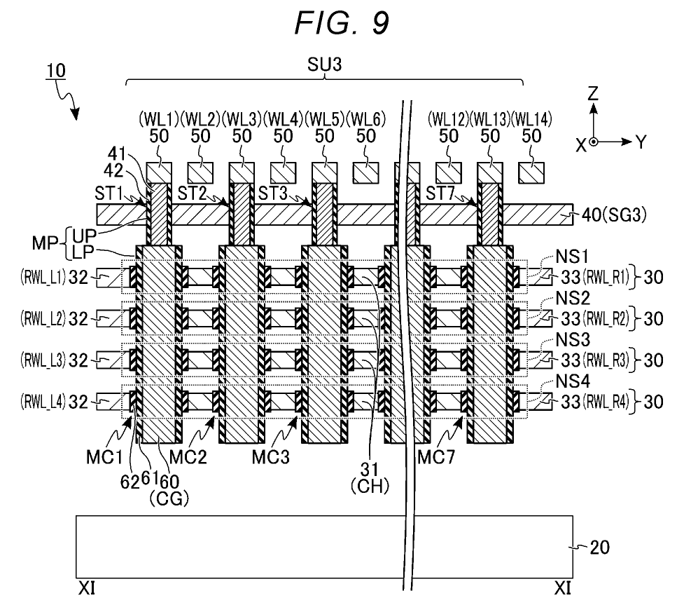

FIG. 9 is a cross-sectional view taken along a line IX-IX in FIG. 8 and illustrating an example of the cross-sectional structure of the memory cell array 10 in the memory device 1. FIG. 9 shows a YZ cross section including the string unit SU3 (that is, the odd string unit SUo). A YZ cross section of the even string unit SUe is similar to the YZ cross section of the odd string unit SUo except that the word line WL (conductor layer 50) connected to the memory pillar MP is changed from the odd word line WLo to the even word line WLe.

As illustrated in FIG. 9, seven intersections between each semiconductor layer 30 and each of seven lower pillars LP aligned in the Y direction function as the memory cell transistors MC1 to MC7 in the order from the diffusion region 32 (read write line RWL_L) side to the diffusion region 33 (read write line RWL_R) side. Seven intersections between the conductor layer 40 and each of seven upper pillars UP aligned in the Y direction function as the select transistors ST1 to ST7 in the order from the diffusion region 32 (read write line RWL_L) side to the diffusion region 33 (read write line RWL_R) side.

The associated conductor layer 50 is provided on the semiconductor member 41 provided in the upper pillar UP of each memory pillar MP. The semiconductor member 41 (channel of the select transistor ST) of the upper pillar UP is provided on the conductive member 60 (control gate line CG) provided in the lower pillar LP of each memory pillar MP. In each memory pillar MP, the conductive member 60 of the lower pillar LP is electrically connected to the semiconductor member 41 of the upper pillar UP. For example, a diameter of a lower end portion of the upper pillar UP is less than a diameter of an upper end portion of the lower pillar LP.

In each lower pillar LP, the stacked film 61 is provided continuously between two memory cell transistors MC adjacent in the Z direction. Therefore, the stacked film 61 has a substantially cylindrical shape in the lower pillar LP. Meanwhile, the stacked film 62 is provided for each memory cell transistor MC. Specifically, of the two memory cell transistors MC adjacent in the Z direction, the stacked film 62 of one memory cell transistor MC and the stacked film 62 of the other memory cell transistor MC are separated in the Z direction. That is, the stacked film 62 is provided in a ring shape at each intersection between the lower pillar LP and the semiconductor layer 30.

### 6 Cross-Sectional Structure of String Unit SU

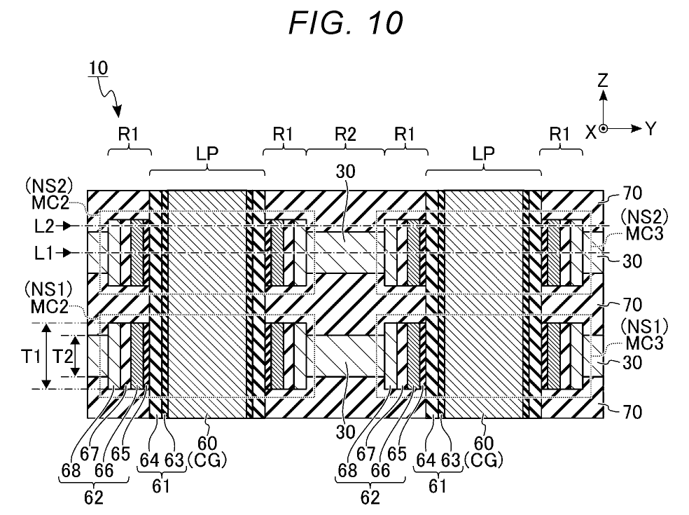

FIG. 10 is a cross-sectional view illustrating an example of a detailed cross-sectional structure of the string unit SU in the memory cell array 10 in the memory device 1. FIG. 10 shows a detailed YZ cross section of a region including the memory cell transistors MC2 and MC3 of two NAND strings NS1 and NS2 adjacent in the Z direction. A structure of the YZ cross section including the memory cell transistors MC of the two NAND strings NS adjacent in the Z direction in other regions may be similar to the YZ cross section illustrated in FIG. 10.

As illustrated in FIG. 10, the memory cell array 10 further includes a plurality of insulator layers 70. The stacked film 61 includes, for example, a high dielectric film 63 and an insulating film 64. The stacked film 62 includes, for example, a high dielectric film 65, a storage film 66, an insulating film 67, and a semiconductor film 68.

Each insulator layer 70 is an interlayer insulating film provided between the semiconductor layers 30 adjacent in the Z direction. The memory cell array 10 has a structure in which the plurality of insulator layers 70 and the plurality of semiconductor layers 30 are alternately stacked one by one in the Z direction. Each insulator layer 70 includes a portion that the plurality of lower pillars LP penetrate. The insulator layer 70 mainly contains, for example, silicon oxide (SiO).

Each stacked film 61 (high dielectric film 63 and insulating film 64) is continuously provided between the two memory cell transistors MC adjacent in the Z direction. The high dielectric film 63 covers a side surface of the conductive member 60. The insulating film 64 covers a side surface of the high dielectric film 63. The high dielectric film 63 mainly contains, for example, aluminum oxide (AlO). The insulating film 64 mainly contains, for example, silicon oxide (SiO).

Each stacked film 62 (high dielectric film 65, storage film 66, insulating film 67, and semiconductor film 68) is provided separately between the two memory cell transistors MC adjacent in the Z direction. The high dielectric film 65 covers a side surface of the insulating film 64. The storage film 66 covers a side surface of the high dielectric film 65. The insulating film 67 covers a side surface of the storage film 66. The semiconductor film 68 covers a side surface of the insulating film 67. A side surface of the semiconductor film 68 is in contact with the semiconductor layer 30. The high dielectric film 65 mainly contains, for example, hafnium silicate (HfSiO). The insulating film 67 mainly contains, for example, silicon oxide (SiO). The semiconductor film 68 mainly contains, for example, silicon (Si). The insulating film 67 functions as a tunnel insulating film of the memory cell transistor MC. A set of the high dielectric films 63 and 65 and the insulating film 64 functions as a gate insulating film of the memory cell transistor MC. The semiconductor film 68 functions as the channel CH of the memory cell transistor MC.

The storage film 66 functions as a data storage layer (or a charge storage film) of the memory cell transistor MC and is configured to store charges (electrons or holes). Any material may be used for the storage film 66 as long as the material has a function of changing a threshold voltage of the memory cell transistor MC due to a physical phenomenon. The storage film 66 may be a ferroelectric material of which a direction of electric dipole changes by an electric field, or may be a variable resistance element (e.g., phase change material, metal oxide, or the like) of which a resistance value changes by an electric field. When the storage film 66 is a conductor such as polysilicon, the memory cell transistor MC functions as a floating gate type memory cell. When the storage film 66 is configured with an insulator such as silicon nitride, the memory cell transistor MC functions as a silicon-oxide-nitride-oxide-silicon (SONOS) type or a metal-oxide-nitride-oxide-silicon (MONOS) type memory cell.

Hereinafter, in a plan view, a region in which the stacked film 62 of each memory cell transistor MC is provided is referred to as a "region R1". In a plan view, a region of the semiconductor layer 30 corresponding to a region between the two memory cell transistors MC adjacent in the X direction or the Y direction is referred to as a "region R2". Each of the regions R1 and R2 corresponds to a region in which a channel of the NAND string NS may be formed during the read or write operation. In the memory device 1, a thickness T1 of the semiconductor film 68 provided in the region R1 in the Z direction is greater than a thickness T2 of the semiconductor layer 30 provided in the region R2 in the Z direction.

Each of the thickness T1 of the semiconductor film 68 and the thickness T2 of the semiconductor layer 30 may be referred to as a channel film thickness. A first layer L1 illustrated in FIG. 10 indicates a layer parallel to a surface of the semiconductor substrate 20, and includes both the semiconductor layer 30 and the semiconductor film 68. A second layer L2 illustrated in FIG. 10 indicates a layer parallel to the surface of the semiconductor substrate 20, and includes the semiconductor film 68 but does not include the semiconductor layer 30.

### 7 Cross-Sectional Structure of First Layer L1

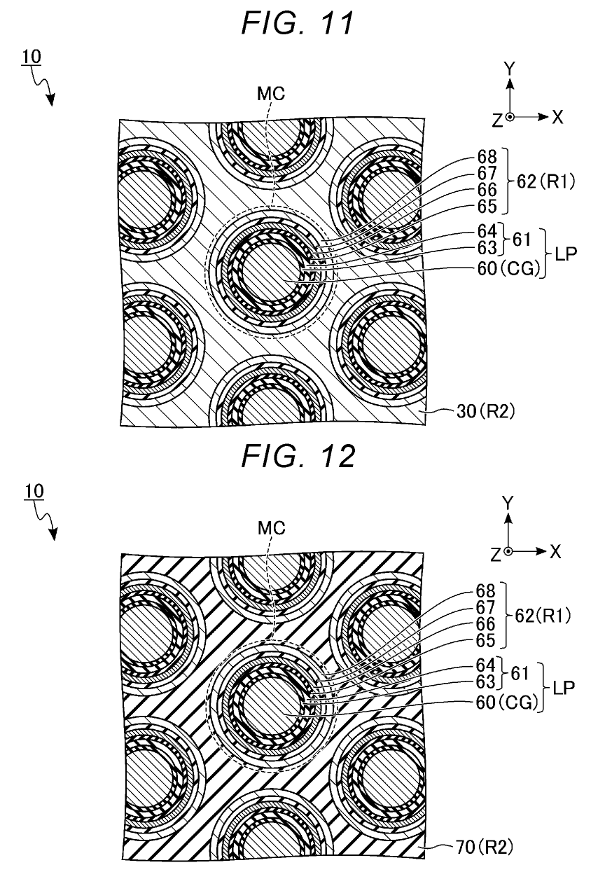

FIG. 11 is a cross-sectional view illustrating an example of a detailed cross-sectional structure of the first layer L1 in the memory cell array 10 in the memory device 1. As illustrated in FIG. 11, in an XY cross section corresponding to the first layer L1, the high dielectric film 63 and the insulating film 64 provided in the stacked film 61, and the high dielectric film 65, the storage film 66, the insulating film 67, and the semiconductor film 68 provided in the stacked film 62 are each provided in a ring shape. In the two lower pillars LP adjacent in the X direction or the Y direction, the semiconductor film 68 in the region R1 surrounding one lower pillar LP and the semiconductor film 68 in the region R1 surrounding the other lower pillar LP are connected via the semiconductor layer 30 in the region R2.

### 8 Cross-Sectional Structure of Second Layer L2

FIG. 12 is a cross-sectional view illustrating an example of a detailed cross-sectional structure of the second layer L2 in the memory cell array 10 in the memory device 1. As illustrated in FIG. 12, in an XY cross section corresponding to the second layer L2, of the two lower pillars LP adjacent in the X direction or the Y direction, the semiconductor film 68 in the region R1 surrounding one lower pillar LP and the semiconductor film 68 in the region R1 surrounding the other lower pillar LP are separated by the insulator layer 70 in the region R2. In other words, each insulator layer 70 includes a portion provided between the two semiconductor films 68 adjacent at the same height. The rest of the structure of the second layer L2 is the same as the structure of the first layer L1.

### 2 Manufacturing Method

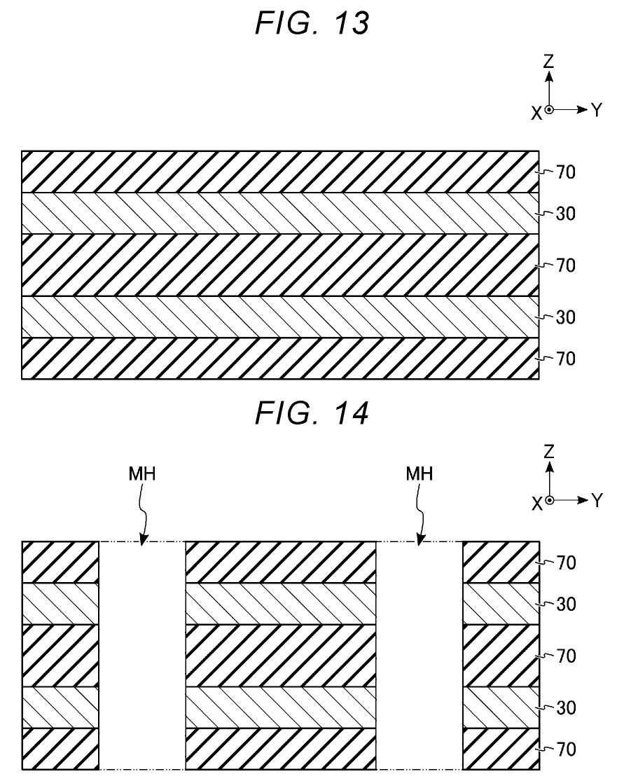

Next, an example of a series of steps from formation of a stacked structure corresponding to the memory cell array 10 to formation of the control gate lines CG will be described as a manufacturing method of the memory device 1 with reference to FIGS. 13 to 19. Each of FIGS. 13 to 19 is a cross-sectional view illustrating an example of a cross-sectional structure in a manufacturing process of the memory device 1.

First, as illustrated in FIG. 13, the insulator layers 70 and the semiconductor layers 30 are alternately stacked. An impurity diffusion step may be inserted when each semiconductor layer 30 is formed, and the channel region 31, the diffusion regions 32 to 35, and the plurality of insulating regions INS may be formed in the semiconductor layer 30.

Next, as illustrated in FIG. 14, a plurality of memory holes MH corresponding to the plurality of lower pillars LP are formed. Each memory hole MH is formed to penetrate or pass through at least the plurality of stacked insulator layers 70 and the plurality of semiconductor layers 30.

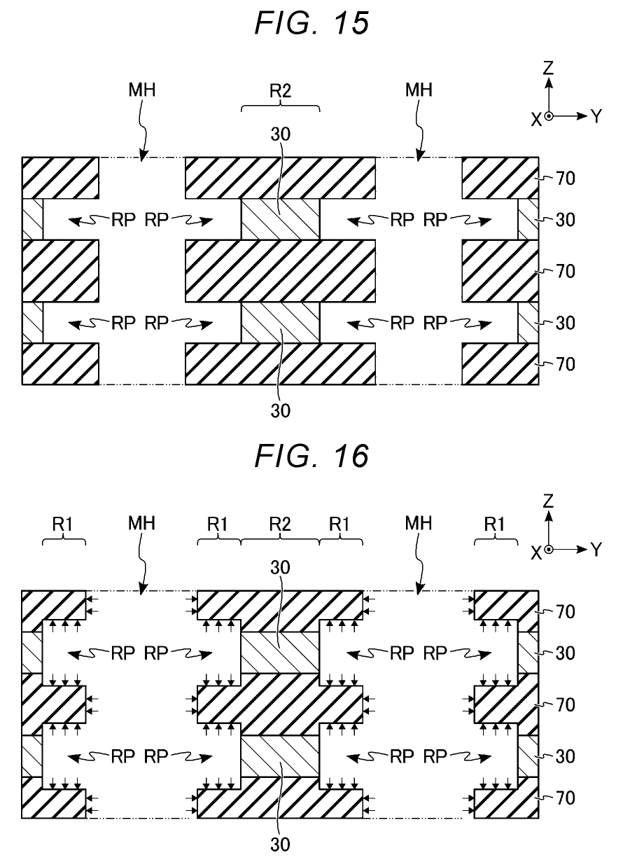

Next, as illustrated in FIG. 15, a wet etching process is performed, and a portion of the semiconductor layer 30 is selectively removed via each memory hole MH. Thereby, a recessed portion RP is formed at a portion where each memory hole MH and each semiconductor layer 30 intersect. A portion between the recessed portions RP of two adjacent memory holes MH corresponds to the region R2.

Next, as illustrated in FIG. 16, the wet etching process is performed, and a portion of the insulator layer 70 is selectively removed via each memory hole MH. Accordingly, a diameter of the memory hole MH increases. A thickness of the insulator layer 70 in the Z direction is reduced in a portion corresponding to the region R1. That is, each recessed portion RP is expanded in the Z direction.

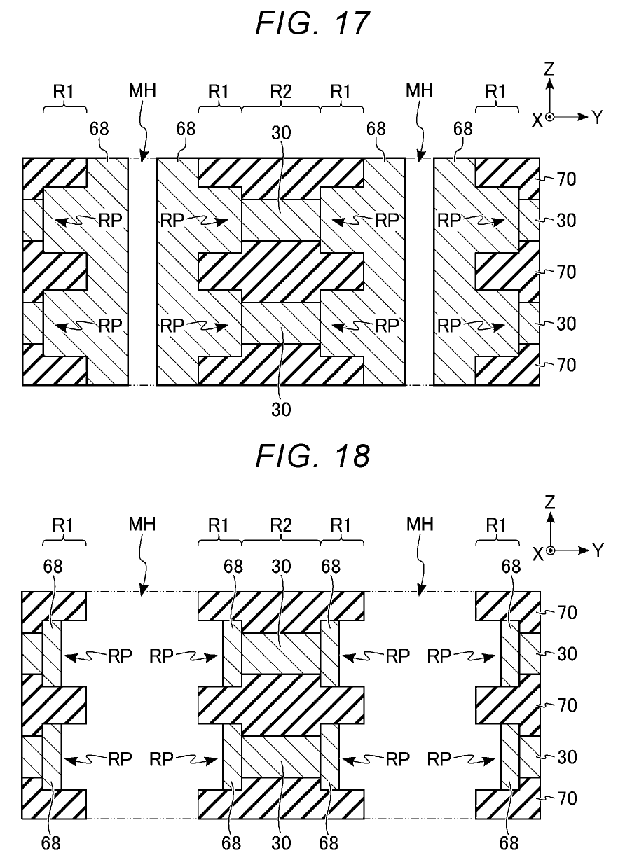

Next, as illustrated in FIG. 17, the semiconductor film 68 is formed to fill each recessed portion RP of each memory hole MH. The semiconductor film 68 of each memory hole MH is electrically connected to each semiconductor layer 30. In the present step, a film formation amount of the semiconductor film 68 is controlled not to completely fill each memory hole MH.

Next, as illustrated in FIG. 18, the wet etching process is performed, and a portion of the semiconductor film 68 is selectively removed via each memory hole MH. Thereby, a structure in which the semiconductor film 68 remains is formed in each recessed portion RP (region R1) of each memory hole MH. A thickness of the semiconductor film 68 remaining in each recessed portion RP (region R1) in the Z direction is greater than a thickness of the semiconductor layer 30 in the region R2 in the Z direction.

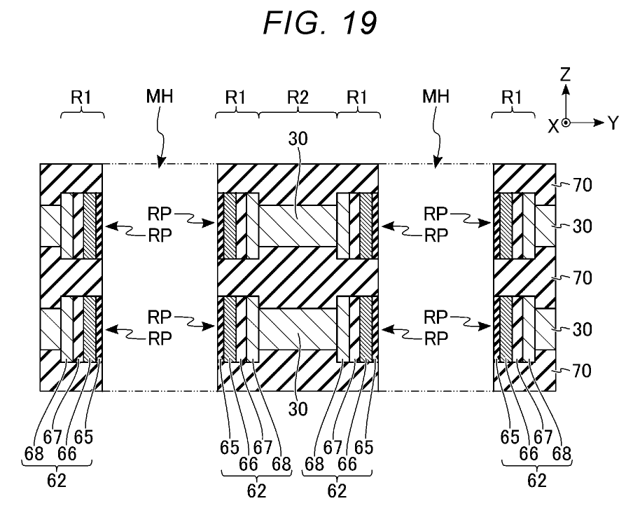

Next, as illustrated in FIG. 19, the insulating film 67, the storage film 66, and the high dielectric film 65 are formed in this order, and the insulating film 67, the storage film 66, and the high dielectric film 65 formed outside each recessed portion RP are removed. Thereby, the structure of the stacked film 62 is completed in each recessed portion RP.

Thereafter, although not illustrated, the insulating film 64, the high dielectric film 63, and the conductive member 60 are formed in this order, and the insulating film 64, the high dielectric film 63, and the conductive member 60 formed outside each memory hole MH are removed. Thereby, a structure corresponding to the lower pillar LP as illustrated in FIG. 10 is completed in each memory hole MH.

### 3 Operation

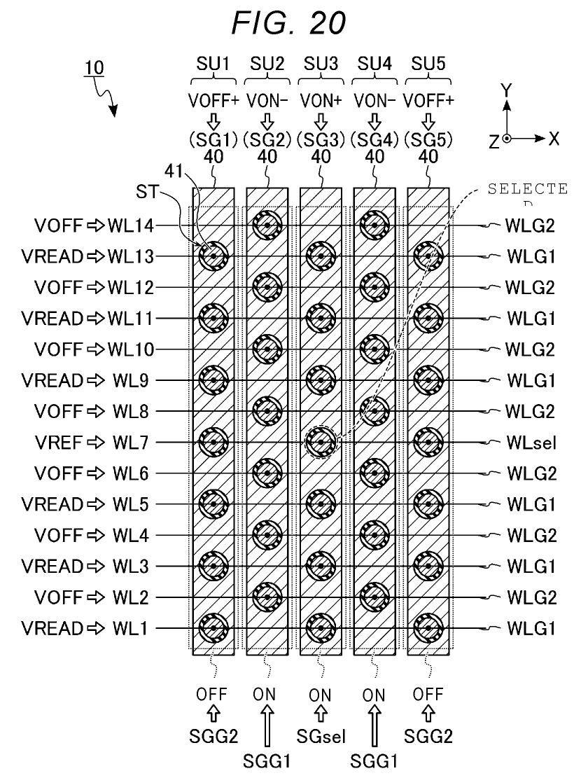

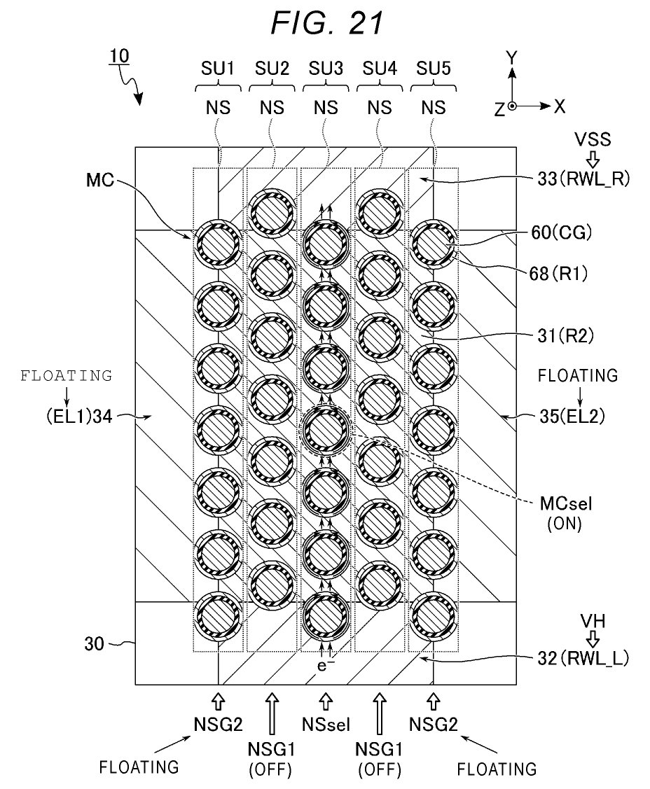

Next, the read operation of the memory device 1 will be described as an example of the operation of the memory device 1. Each of FIGS. 20 and 21 is a schematic diagram illustrating an example of the read operation of the memory device 1. FIG. 20 shows an example of voltages applied to each word line WL and each select gate line SG at a certain timing of the read operation. FIG. 21 shows an example of voltages applied to the read write lines RWL_L and RWL_R, states of the erase lines EL1 and EL2, and states of each NAND string NS at a certain timing of the read operation. In the example, the read operation is performed on the memory cell transistor MC associated with the select gate line SG3 and the word line WL7.

Hereinafter, the voltages applied to each element are assumed to be applied based on control of the control circuit 12. A threshold voltage when the memory cell transistor MC stores data of "1" is assumed to be higher than a threshold voltage when the memory cell transistor MC stores data of "0". Hereinafter, the memory cell transistor MC to be read is referred to as a "memory cell transistor MCsel". The memory cell transistor MC not to be read is referred to as a "non-selected memory cell transistor MC". The select gate line SG associated with the memory cell transistor MCsel, that is, the selected select gate line SG, is referred to as a "select gate line SGsel". A set including select gate lines SG adjacent to the select gate line SGsel is referred to as a "select gate line group SGG1". A set including select gate lines SG separated from the select gate line SGsel by one or more select gate lines SG is referred to as a "select gate line group SGG2". The NAND string NS associated with the select gate line SGsel, that is, the selected NAND string NS is referred to as a "NAND string NSsel". The NAND string NS associated with the select gate line group SGG1 is referred to as a "NAND string group NSG1". The NAND string NS associated with the select gate line group SGG2 is referred to as a "NAND string group NSG2". The word line WL associated with the memory cell transistor MCsel, that is, the selected word line WL, is referred to as a "word line WLsel". A set that includes elements of a set including the selected word line WLsel but does not include the selected word line WLsel, in which the set including the selected word line WLsel is one of the set including the odd word lines WLo and the set including the even word lines WLe, is referred to as a "word line group WLG1". A set that includes elements of a set not including the selected word line WLsel, in which the set not including the selected word line WLsel is the other of the set including the odd word lines WLo and the set including the even word lines WLe, is referred to as a "word line group WLG2".

As illustrated in FIG. 20, in the read operation, a read voltage VREF is applied to the word line WLsel. A read pass voltage VREAD is applied to each word line WL of the word line group WLG1. An off-voltage VOFF is applied to each word line WL of the word line group WLG2. An on-voltage VON+ is applied to the select gate line SGsel. An on-voltage VON- is applied to the select gate lines SG of the select gate line group SGG1. An off-voltage VOFF+ is applied to the select gate lines SG of the select gate line group SGG2.

The read voltage VREF is a voltage used to determine data of the memory cell transistor MCsel. The memory cell transistor MCsel to which the read voltage VREF is applied is turned on or off according to a threshold voltage based on data stored in the memory cell transistor MCsel. That is, the read voltage VREF is set to a value between the threshold voltage when the memory cell transistor MC stores data of "1" and the threshold voltage when the memory cell transistor MC stores data of "0".

The read pass voltage VREAD is a voltage applied to the non-selected memory cell transistors MC of the NAND string NSsel. The memory cell transistors MC to which the read pass voltage VREAD is applied are turned on regardless of data stored in the memory cell transistors MC. That is, the read voltage VREAD is set to a value higher than the threshold voltage when the memory cell transistor MC stores data of "1".

The off-voltage VOFF is a voltage applied to the memory cell transistors MC of the NAND string group NSG1. The memory cell transistors MC to which the off-voltage VOFF is applied are turned off regardless of data stored in the memory cell transistors MC. That is, the off-voltage VOFF is set to a value lower than the threshold voltage when the memory cell transistor MC stores data of "0". A relationship between values of various voltages applied to the word line WL is represented by VREAD > VREF > VOFF.

The on-voltage VON+ is a voltage for turning on the plurality of select transistors ST connected to the select gate line SGsel. Therefore, a difference between the on-voltage VON+ applied to the select gate line SGsel and the read pass voltage VREAD applied to the word lines WL of the word line group WLG1 is set to a value greater than a threshold voltage of the select transistor ST.

The on-voltage VON- is a voltage for turning on the plurality of select transistors ST connected to the select gate lines SG of the select gate line group SGG1. Therefore, a difference between the on-voltage VON- applied to the select transistors ST of the select gate line group SGG1 and the off-voltage VOFF applied to the word lines WL of the word line group WLG2 is set to a value greater than the threshold voltage of the select transistor ST.

The off-voltage VOFF+ is a voltage for turning off the plurality of select transistors ST connected to the select gate lines SG of the select gate line group SGG2. A difference between the off-voltage VOFF+ applied to the select transistors ST of the select gate line group SGG2 and the read pass voltage VREAD applied to the word lines WL of the word line group WLG1 is set to a value lower than the threshold voltage of the select transistor ST. A relationship of values of various voltages applied to the select gate line SG is represented by VON+ > VON- > VOFF+.

As illustrated in FIG. 21, a first voltage VH is applied to the read write line RWL_L. For example, a second voltage VSS is applied to the read write line RWL_R. Each of the erase lines EL1 and EL2 is controlled to be in a floating state.

The first voltage VH corresponds to, for example, a power supply voltage on a high potential side of the memory device 1. The second voltage VSS corresponds to, for example, a power supply voltage on a low potential side of the memory device 1. A relationship between values of various voltages applied to the read write lines RWL_L and RWL_R is represented by VH > VSS.

As described above, in the read operation, the plurality of select transistors ST connected to the select gate lines SG of the select gate line group SGG2 are turned off. Therefore, the plurality of control gate lines CG connected to the plurality of memory cell transistors MC provided in the NAND string group NSG2 are set to the floating state. Accordingly, no channel is formed in the NAND strings NS of the NAND string group NSG2.

In the read operation, the plurality of select transistors ST connected to the select gate lines SG of the select gate line group SGG1 are turned on. Therefore, the off-voltage VOFF is applied to each of the plurality of control gate lines CG connected to the plurality of memory cell transistors MC provided in the NAND string group NSG1 via the associated select transistor ST. Thereby, the plurality of memory cell transistors MC provided in the NAND string group NSG1 are turned off. Therefore, no channel is formed in the NAND strings NS of the NAND string group NSG1. Each NAND string NS of the NAND string group NSG1 is able to reduce an effect on reading data from the NAND string NSsel.

In the read operation, the plurality of select transistors ST connected to the select gate line SGsel are turned on. Therefore, the read pass voltage VREAD is applied to the control gate lines CG connected to the memory cell transistors MC other than the memory cell transistor MCsel to be read in the NAND string NSsel via the associated select transistors ST. The read voltage VREF is applied to the control gate lines CG connected to the memory cell transistor MCsel to be read via the associated select transistors ST. As a result, in the NAND string NSsel, whether a channel is formed from the read write line RWL_R to the read write line RWL_L is determined depending on whether the memory cell transistor MCsel is turned on or off. That is, whether electrons (e-) are capable of moving from the read write line RWL_R to the read write line RWL_L is determined according to a relationship between the threshold voltage of the memory cell transistor MCsel and the read voltage VREF.

For example, when the memory cell transistor MCsel stores data of "1", the memory cell transistor MCsel is turned off. Then, in the NAND string NSsel, the memory cell transistor MCsel blocks the channel from the read write line RWL_R to the read write line RWL_L. Here, a potential of the read write line RWL_L is maintained at VH. In contrast, when the memory cell transistor MCsel stores data of "0", as illustrated in FIG. 21, the memory cell transistor MCsel is turned on. Then, in the NAND string NSsel, a channel is formed from the read write line RWL_R to the read write line RWL_L. Here, electrons (e-) move via the semiconductor film 68 near each memory cell transistor MC of the NAND string NSsel (region R1), and move via the semiconductor layer 30 (channel region 31) between the two adjacent memory cell transistors MC of the NAND string NSsel (region R2). Then, the potential of the read write line RWL_L drops from VH to, for example, VSS. As a result, the read circuit 18 is capable of determining data stored in the memory cell transistor MCsel by sensing voltage change of the read write line RWL_L by a sense amplifier.

### 4 Effects

According to the memory device 1, improvement in performance of the memory device can be achieved. Effects will be described in detail below.

Matrix cell stack (MaCS) is known as a type of a memory device having a vertical gate (VG) cell structure. MaCS has a structure in which semiconductor films used as channel of the NAND strings NS (hereinafter referred to as channel semiconductor films) are not physically separated between NAND strings NS adjacent in the same layer. A current applied during operation of MaCS flows in an interface between a tunnel insulating film and a channel semiconductor film in an outer periphery of the memory cell transistor MC. Then, the current flows in an interface between an interlayer insulating film and a channel semiconductor film in a fringe portion of two adjacent memory cell transistors MC.

For example, when the channel semiconductor film is formed uniformly thick, it is difficult to form an inversion layer since electric field lines from the control gate line CG are unlikely to reach the fringe portion. As a result, a resistance value of the fringe portion increases. As a method for reducing the resistance value of the fringe portion, a method of forming the channel semiconductor film to be uniformly thin is considered. Here, it is easier for the electric field lines from the control gate line CG to reach the fringe portion. As a result, the inversion layer is easily formed, and the resistance value of the fringe portion can be reduced. In contrast, as the channel semiconductor film becomes thinner, a resistance value in the outer periphery of the memory cell transistor MC increases.

As such, to reduce a channel resistance of the NAND string NS, it is preferable that the channel semiconductor film in the fringe portion is thin and the channel semiconductor film in the outer periphery of the memory cell transistor MC is thick.

Therefore, the memory cell array 10 in the memory device 1 includes a thick channel semiconductor film (semiconductor film 68) in the outer periphery of the memory cell transistor MC (region R1), and a thin channel semiconductor film (channel region 31 of the semiconductor layer 30) in the fringe portion (region R2).

Thereby, the memory device 1 is able to reduce both the resistance value in the outer periphery (region R1) and the resistance value in the fringe portion (region R2) in the memory cell transistor MC in the NAND string NS. As a result, the memory device 1 is able to increase an amount of current flowing in the NAND string NS, and is able to improve performance of the memory device 1.

By forming a thin channel semiconductor film (channel region 31 of the semiconductor layer 30) in the fringe portion, it is possible to prevent electrons from moving between two NAND strings NS adjacent to the selected NAND string NSsel during the write or read operation. As a result, in the memory device 1, boost characteristics can be improved, and performance of the memory device 1 can be improved.

In the memory device 1, "boost" means an operation for preventing erroneous writing into the non-selected memory cell transistor MC. For example, when writing data into the selected memory cell transistor MCsel, data may also be written into the non-selected memory cell transistors MC aligned in the Z direction and sharing the word line WL (control gate line CG). To prevent such a situation, a potential of the semiconductor layer 30 facing the non-selected memory cell transistors MC in the planar direction is boosted in advance. Accordingly, a potential difference between the selected word line WLsel (control gate line CG) and the semiconductor layer 30 associated with the non-selected memory cell transistors MC decreases, thereby preventing erroneous writing into the non-selected memory cell transistors MC. In other words, boost characteristics indicate that the potential of the semiconductor layer 30 associated with the non-selected memory cell transistors MC easily increases.

### 5 Others

The circuit configuration, the planar layout, and the cross-sectional structure of the memory device 1 may be modified as appropriate. For example, the number of wiring layers and contacts provided in the memory device 1 may be modified as appropriate according to the circuit design. Each of the upper pillar UP and the lower pillar LP may have a tapered shape, an inverse tapered shape, or a bowing shape. A contact plug may be inserted between the upper pillar UP and the conductor layer 50 (word line WL). The XY cross-sectional shape of the conductive member 60 (control gate line CG) is not limited to a circle, and may be an ellipse, a rectangle, a polygon, or the like.

In the present specification, "connection" indicates electrical connection, and includes, for example, connection in which another element is interposed therebetween. "Electrical connection" may indicate connection via an insulator as long as the operation is similar to that of electrical connection. "Region" may be considered as a configuration provided in the semiconductor substrate 20. For example, when the semiconductor substrate 20 is defined to include the regions R1 and R2, the regions R1 and R2 may be associated with regions above the semiconductor substrate 20. "Height" corresponds to, for example, a distance from the semiconductor substrate 20 in the Z direction. "Conductivity type" corresponds to a P-type or an N-type. "Diameter" indicates an inner diameter of a hole or an outer diameter of a pillar in a cross section parallel to the surface of the semiconductor substrate 20 (XY cross section).

In the present specification, "high dielectric film" is also referred to as a high-k film (high-dielectric constant film). The high dielectric film has a higher dielectric constant than silicon oxide. The high dielectric film is able to achieve equivalent insulation performance with a thinner film than silicon oxide. Hafnium (Hf)-based oxide or zirconium (Zr)-based oxide may be used as each of the high dielectric films 63 and 65.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A memory device comprising:
a plurality of semiconductor layers separated from each other in a first direction;
a plurality of conductive members penetrating the semiconductor layers in the first direction;
a plurality of first insulating films surrounding side surfaces of the conductive members;
a plurality of charge storage films between the first insulating films and one of the semiconductor layers;
a plurality of second insulating films between the charge storage films and said one of the semiconductor layers; and
a plurality of semiconductor films between the second insulating films and said one of the semiconductor layers, and in contact with said one of the semiconductor layers, wherein
a thickness of each of the semiconductor layers in the first direction is less than a thickness of said one of the semiconductor films in the first direction.

2. The memory device according to claim 1, further comprising:
a plurality of first transistors connected to first conductive members of the conductive members;
a first select gate line connected to gates of the first transistors;
a plurality of second transistors connected to second conductive members of the conductive members; and
a second select gate line connected to gates of the second transistors.

3. The memory device according to claim 2, wherein
the first and second select gate lines are adjacent and extend parallel to each other.

4. The memory device according to claim 1, further comprising:
a plurality of conductor layers disposed above the semiconductor layers in the first direction, extending in a second direction intersecting the first direction, arranged in a third direction intersecting the first and second directions, and including first and second conductor layers that are adjacent to each other in the third direction;
a plurality of first pillars penetrating the first conductor layer in the first direction and arranged in the second direction; and
a plurality of second pillars penetrating the second conductor layer in the first direction and arranged in the second direction.

5. The memory device according to claim 4, wherein
transistors are formed at intersections of the first and second pillars with the first and second conductor layers, respectively.

6. The memory device according to claim 4, wherein
the semiconductor layer includes a channel region and first to fourth diffusion regions,
a portion of the channel region faces each of the conductive members,
the first and second diffusion regions each contain a first conductive type impurity and are disposed such that the channel region is interposed in the second direction, and
the third and fourth diffusion regions each contain a second conductive type impurity different from the first conductive type impurity and are disposed such that the channel region is interposed in the third direction.

7. The memory device according to claim 4, further comprising:
a plurality of word lines arranged in the second direction and extending in the third direction above the conductor layers, wherein
the word lines are electrically connected to the conductive members.

8. The memory device according to claim 7, wherein
the word lines include a plurality of first word lines connected to the first pillars and a plurality of second word lines connected to the second pillars.

9. The memory device according to claim 8, wherein
the first and second word lines are disposed alternately in the second direction.

10. The memory device according to claim 1, further comprising:
a plurality of insulator layers stacked alternately with the semiconductor layers, wherein
a portion of one of the insulator layers is located between two of the semiconductor films that are adjacent to each other in the second direction.

11. The memory device according to claim 1, wherein
each of the conductive members includes any of conductive polysilicon containing impurities, metal, and metal silicide.

12. The memory device according to claim 1, wherein
each of the charge storage films is a conductor, and
floating gate type memory cells are formed at intersections between the semiconductor layers and the conductive members.

13. The memory device according to claim 1, wherein
each of the charge storage films is an insulator, and
SONOS type memory cells or MONOS type memory cells are formed at intersections between the semiconductor layers and the conductive members.

14. The memory device according to claim 1, further comprising:
a plurality of first high dielectric films between the conductive members and the first insulating films; and
a plurality of second high dielectric films between the charge storage films and the first insulating films.

15. The memory device according to claim 14, wherein
each of the first high dielectric films contains aluminum oxide, and
each of the second high dielectric films contains hafnium silicate.

16. A memory device comprising:
a plurality of semiconductor portions separated from each other in a first direction;
a plurality of conductive members penetrating the semiconductor portions in the first direction;
a plurality of first insulating films surrounding side surfaces of the conductive members;
a plurality of charge storage films between the first insulating films and one of the semiconductor portions; and
a plurality of second insulating films between the charge storage films and said one of the semiconductor portions, wherein
a thickness of a first part of said one of the semiconductor portions in the first direction is less than a thickness of a second part of said one of the semiconductor portions in the first direction, the second part closer to one of the conductive members than the first part.
